(19) United States
(12) Patent Application Publication
(10) Pub. No.: US 2016/0315197 A1
(43) Pub. Date: Oct. 27, 2016

(54) THIN-FILM TRANSISTOR, PREPARATION METHOD THEREOF, ARRAY SUBSTRATE AND DISPLAY DEVICE

(71) Applicant: BOE TECHNOLOGY GROUP CO., LTD., Beijing (CN)

(72) Inventors: Chienhung LIU, Beijing (CN); Yucheng CHAN, Beijing (CN)

(21) Appl. No.: 15/075,439

(22) Filed: Mar. 21, 2016

(30) Foreign Application Priority Data
Apr. 24, 2015 (CN) 201510203209.2

(51) Int. Cl. H01L 29/786; H01L 27/12; H01L 29/66

(52) U.S. Cl. CPC H01L 29/78606; H01L 29/6675; H01L 29/78672; H01L 27/1222; H01L 27/1274

(57) ABSTRACT

The present invention discloses a thin-film transistor, a preparation method thereof, an array substrate comprising the thin-film transistor, and a display device comprising the array substrate, wherein the preparation method of the thin-film transistor comprises: successively depositing an amorphous silicon thin film and a protective layer thin film on a base substrate; annealing the amorphous silicon thin film so as to transform the amorphous silicon thin film into a poly-silicon thin film; and performing a single patterning process on the poly-silicon thin film and the protective layer thin film to pattern the poly-silicon thin film into an active layer and pattern the protective layer thin film into a protective layer.

### FIELD OF THE INVENTION

The present invention relates to the field of display technology, and particularly relates to a thin-film transistor, a preparation method thereof, an array substrate and a display device.

### BACKGROUND OF THE INVENTION

Generally, a display panel includes an array substrate and an opposite substrate arranged oppositely to the array substrate, wherein the array substrate includes a base substrate and thin-film transistors (TFT for short) located on the base substrate. In the prior art, low temperature poly-silicon (LTPS for short) thin-film transistors have got support from the majority of panel manufacturers, depending on superior stability and high mobility thereof.

In an actual production process, multiple production processes are needed to prepare the LTPS thin-film transistor, and therein, after a production process of forming an active layer (made of poly-silicon) on the base substrate, the base substrate with the active layer formed thereon needs to be transferred to the equipment corresponding to a next production process. However, during the transfer, the surface of the active layer will be exposed to air, and the surface of the active layer may be contaminated, resulting in an impact on the performance of the thin-film transistor. In order to avoid the performance problem of the thin-film transistor caused by the contamination to the active layer, the surface of the active layer will be pre-cleaned before starting the next production process.

However, not only does the pre-cleaning process consume a lot of time, resulting in a long production cycle, but also the active layer will still be exposed to air for some time after the pre-cleaning process is completed, and in this case, secondary contamination will occur inevitably.

### SUMMARY OF THE INVENTION

An object of the present invention is to provide a thin-film transistor, a preparation method thereof, an array substrate including the thin-film transistor, and a display device including the array substrate, which can effectively avoid an active layer from being contaminated during the process of transferring the active layer for a next production process after the process of forming the active layer is completed, thus omitting a process of pre-cleaning the active layer before starting the next production process and further shortening the production cycle.

In order to achieve the above object, the present invention provides a preparation method of a thin-film transistor, including:

successively depositing an amorphous silicon thin film and a protective layer thin film on a base substrate;

annealing the amorphous silicon thin film so as to transform the amorphous silicon thin film into a poly-silicon thin film; and

performing a single patterning process on the poly-silicon thin film and the protective layer thin film to pattern the poly-silicon thin film into an active layer and pattern the protective layer thin film into a protective layer.

Optionally, the thin-film transistor is a top gate type thin-film transistor, and after the step of performing a single patterning process on the poly-silicon thin film and the protective layer thin film, the preparation method further includes:

forming a gate insulating layer on the protective layer;

forming a gate on the gate insulating layer;

forming a passivation layer on the gate;

forming a first via hole and a second via hole respectively in positions, corresponding to two ends of the active layer, on the passivation layer, the gate insulating layer and the protective layer; and

forming a source and a drain on the passivation layer, the source being connected to the active layer through the first via hole, and the drain being connected to the active layer through the second via hole.

Optionally, before the step of successively depositing an amorphous silicon thin film and a protective layer thin film on a base substrate, the preparation method further includes:

forming a buffer layer on the base substrate.

Optionally, the thin-film transistor is a bottom gate type thin-film transistor, and before the step of successively depositing an amorphous silicon thin film and a protective layer thin film on a base substrate, the preparation method further includes:

forming a gate on the base substrate; and

forming a gate insulating layer on the gate;

after the step of performing a single patterning process on the poly-silicon thin film and the protective layer thin film, the preparation method further includes:

forming a third via hole and a fourth via hole respectively in positions, corresponding to two ends of the active layer, on the protective layer; and

forming a source and a drain on the protective layer, the source being connected to the active layer through the third via hole, and the drain being connected to the active layer through the fourth via hole.

Optionally, before the step of annealing the amorphous silicon thin film, the preparation method further includes:

dehydrogenizing the amorphous silicon thin film at a high temperature.

Optionally, the protective layer is made of silicon oxide.

Optionally, the thickness of the protective layer ranges from 30 nm to 40 nm.

In order to achieve the above object, the present invention further provides a thin-film transistor, including: an active layer formed on a base substrate and a protective layer formed on the active layer, the pattern of the protective layer being the same as that of the active layer.

Optionally, the thin-film transistor is a top gate type thin-film transistor, and the thin-film transistor further includes:

a gate insulating layer formed on the protective layer;

a gate formed on the gate insulating layer;

a passivation layer formed on the gate;

a first via hole and a second via hole respectively formed in positions, corresponding to two ends of the active layer, on the passivation layer, the gate insulating layer and the protective layer, and

a source and a drain formed on the passivation layer, the source being connected to the active layer through the first via hole, and the drain being connected to the active layer through the second via hole.

Optionally, the thin-film transistor is a bottom gate type thin-film transistor, and the thin-film transistor further includes:

a gate formed on the base substrate;

a gate insulating layer formed on the gate;

a third via hole and a fourth via hole respectively formed in positions, corresponding to two ends of the active layer, on the protective layer, and

a source and a drain formed on the protective layer, the source being connected to the active layer through the third via hole, and the drain being connected to the active layer through the fourth via hole.

Optionally, the protective layer is made of silicon oxide.

Optionally, the thickness of the protective layer ranges from 30 nm to 40 nm.

In order to achieve the above object, the present invention further provides an array substrate, including a thin-film transistor which is the above thin-film transistor.

In order to achieve the above object, the present invention further provides a display device, including an array substrate which is the above array substrate.

The present invention has the beneficial effects as follows.

The present invention provides a thin-film transistor, a preparation method thereof, an array substrate including the thin-film transistor, and a display device including the array substrate, wherein the preparation method of a thin-film transistor includes: successively depositing an amorphous silicon thin film and a protective layer thin film on a base substrate; annealing the amorphous silicon thin film so as to transform the amorphous silicon thin film into a poly-silicon thin film; and performing a single patterning process on the poly-silicon thin film and the protective layer thin film to pattern the poly-silicon thin film into an active layer and pattern the protective layer thin film into a protective layer. In the technical solutions of the present invention, since the amorphous silicon thin film and the protective layer thin film are successively deposited on the base substrate, and the active layer and the protective layer are formed simultaneously by performing an annealing process and a single patterning process, the protective layer may play a role of protecting the active layer, and protect the active layer from being contaminated during a process of transferring the base substrate formed with the active layer and the protective layer to the equipment corresponding to a next production process. Meanwhile, since the active layer will not be contaminated during the transfer, the active layer does not need a pre-cleaning process before starting the next production process, thereby shortening the whole production cycle.

### BRIEF DESCRIPTION OF THE DRAWINGS

FIG. 1 is a flow diagram of a preparation method of a thin-film transistor provided by a first embodiment of the present invention;

FIG. 2 is a schematic diagram of successively depositing an amorphous silicon thin film and a protective layer thin film on a base substrate;

FIG. 3 is a schematic structure diagram of forming an active layer and a protective layer;

FIG. 4 is a flow diagram of a preparation method of a thin-film transistor provided by a second embodiment of the present invention;

FIG. 5 is a schematic structure diagram of forming a buffer layer on the base substrate;

FIG. 6 is a schematic structure diagram of forming a gate insulating layer on the protective layer in the second embodiment of the present invention;

FIG. 7 is a schematic structure diagram of forming a gate on the gate insulating layer in the second embodiment of the present invention;

FIG. 8 is a schematic structure diagram of forming a passivation layer on the gate in the second embodiment of the present invention;

FIG. 9 is a schematic structure diagram of forming a first via hole and a second via hole in the second embodiment of the present invention;

FIG. 10 is a schematic structure diagram of forming a source and a drain on the passivation layer in the second embodiment of the present invention;

FIG. 11 is a flow diagram of a preparation method of a thin-film transistor provided by a third embodiment of the present invention;

FIG. 12 is a schematic structure diagram of forming a gate and a gate insulating layer in the third embodiment of the present invention;

FIG. 13 is a schematic structure diagram of forming a third via hole and a fourth via hole in the third embodiment of the present invention; and

FIG. 14 is a schematic structure diagram of forming a source and a drain on the protective layer in the third embodiment of the present invention.

### DETAILED DESCRIPTION OF THE EMBODIMENTS

To make those skilled in the art understand the technical solutions of the present invention better, a thin-film transistor, a preparation method thereof, an array substrate and a display device provided by the present invention will be described in detail below in conjunction with the accompanying drawings.

FIG. 1 is a flow diagram of a preparation method of a thin-film transistor provided by a first embodiment of the present invention, and the preparation method of a thin-film transistor includes steps 101 to 103.

At step 101, an amorphous silicon thin film and a protective layer thin film are successively deposited on a base substrate.

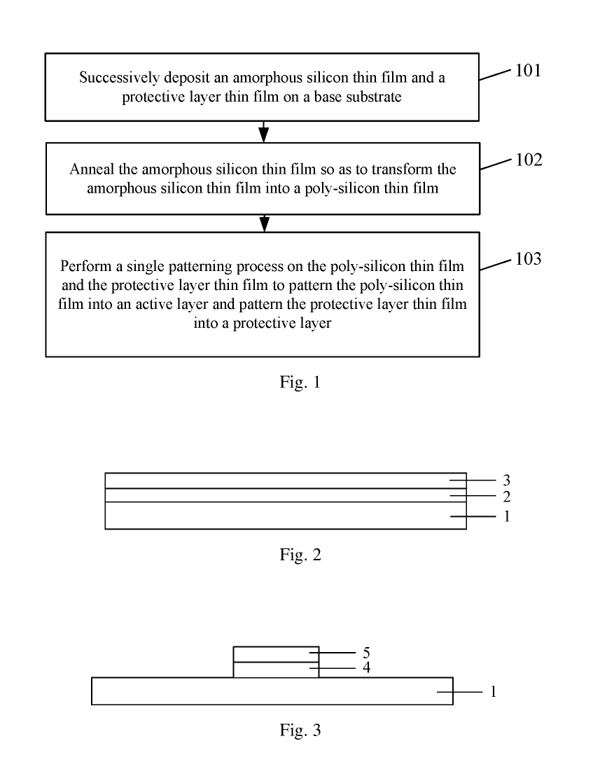

FIG. 2 is a schematic diagram of successively depositing an amorphous silicon thin film and a protective layer thin film on a base substrate, and as shown in FIG. 2, a layer of amorphous silicon thin film 2 and a layer of protective layer thin film 3 may be successively deposited on a base substrate 1 through a plasma enhanced chemical vapor deposition (PECVD for short) method. Optionally, the thickness of the amorphous silicon thin film 2 ranges from 40 nm to 50 nm, the protective layer thin film 3 is made of silicon oxide (SiOₓ) and the thickness thereof ranges from 30 nm to 40 nm.

At step 102, the amorphous silicon thin film is annealed to transform the amorphous silicon thin film into a poly-silicon thin film.

In the step 102, an excimer laser annealing (ELA for short) treatment is performed on the structure obtained in the step 101 so as to transform the amorphous silicon thin film into the poly-silicon thin film.

At step 103, a single patterning process is performed on the poly-silicon thin film and the protective layer thin film to pattern the poly-silicon thin film into an active layer and pattern the protective layer thin film into a protective layer.

FIG. 3 is a schematic structure diagram of forming an active layer and a protective layer, and as shown in FIG. 3, a single patterning process is performed on the poly-silicon thin film and the protective layer thin film by using an existing mask for preparing an active layer, so as to pattern the poly-silicon thin film 2 into an active layer 4 and pattern the protective layer thin film 3 into a protective layer 5; the shape of the protective layer 5 is the same as that of the active layer 4, and the protective layer 5 covers the active layer 4 completely. As the protective layer 5 and the active layer 4 may be prepared by performing a single patterning process with the existing mask for preparing an active layer, a separate mask for forming the protective layer 5 is not needed, so that the cost will not be increased.

Optionally, between the step 101 and the step 102, the method further includes:

step 101a: dehydrogenizing the amorphous silicon thin film at a high temperature.

Specifically, the base substrate formed with the amorphous silicon thin film and the protective layer thin film and obtained in the step 101 is sent to a high temperature furnace to be subjected to a high temperature treatment, in order to dehydrogenize the amorphous silicon thin film (reduce a hydrogen content in the amorphous silicon thin film 2), and the hydrogen content in the amorphous silicon thin film is generally controlled to be not greater than 2%.

It should be noted that the patterning process in the application refers to a process including photoresist coating, exposure, development, etching, photoresist stripping, etc.

In the embodiment, since the protective layer 5 is formed on the active layer 4 while the active layer 4 is formed, the protective layer 5 may play a role of protecting the active layer 4, so that the active layer 4 can be prevented from being contaminated during the process of transferring the base substrate formed with the active layer 4 and the protective layer 5 to the equipment corresponding to a next production process. Meanwhile, since the active layer 4 will not be contaminated during transfer, the active layer 4 does not need a pre-cleaning process before starting the next production process, thereby shortening the whole production cycle.

The first embodiment of the present invention further provides a thin-film transistor which may be prepared through the above steps 101 to 103, and an intermediate structure of the thin-film transistor during the preparation process may be apparent with reference to FIG. 3. Specifically, the thin-film transistor includes an active layer 4 formed on a base substrate 1 and a protective layer 5 formed on the active layer 4, and the pattern of the protective layer 5 is the same as that of the active layer 4. Optionally, the protective layer thin film 3 is made of silicon oxide (SiOₓ) and the thickness of the protective layer thin film 3 ranges from 30 nm to 40 nm.

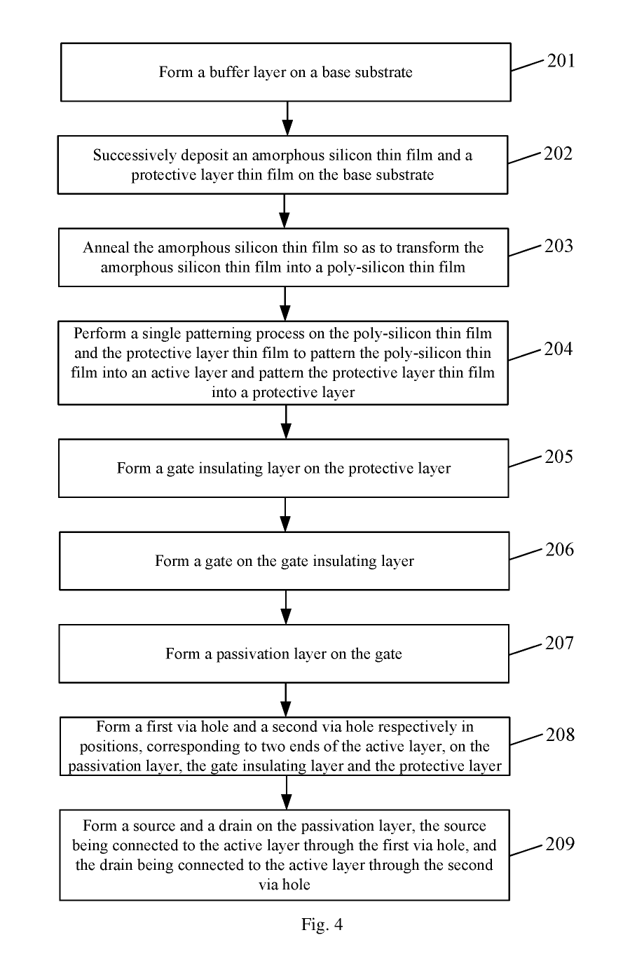

As a specific implementation of the present invention, FIG. 4 shows a flow diagram of a preparation method of a thin-film transistor provided by a second embodiment of the present invention, as shown in FIG. 4, the thin-film transistor is a top gate type thin-film transistor, and the preparation method of the thin-film transistor includes steps 201 to 209.

At step 201, a buffer layer is formed on a base substrate.

FIG. 5 is a schematic structure diagram of forming a buffer layer on a base substrate, and as shown in FIG. 5, a layer of silicon oxide thin film and a layer of silicon nitride thin film can be successively deposited on a base substrate 1 through a PECVD method, to form a buffer layer 6 of a double-layer structure.

It should be noted that the buffer layer 6 in the embodiment may also be of a single-layer structure with a silicon oxide thin film or a silicon nitride thin film only.

The buffer layer in the embodiment plays a role of isolating the base substrate from the active layer, in order to avoid silicon in the base substrate influencing the performance of the subsequently formed active layer. However, the buffer layer 6 is optional.

At step 202, an amorphous silicon thin film and a protective layer thin film are successively deposited on the buffer layer.

At step 203, the amorphous silicon thin film is annealed so as to transform the amorphous silicon thin film into a poly-silicon thin film.

At step 204, a single patterning process is performed on the poly-silicon thin film and the protective layer thin film to pattern the poly-silicon thin film into an active layer and pattern the protective layer thin film into a protective layer.

The specific processes of the step 202 to step 204 may be apparent with reference to the specific description of the step 101 to step 103 in the first embodiment, and are not repeatedly described here.

At step 205, a gate insulating layer is formed on the protective layer.

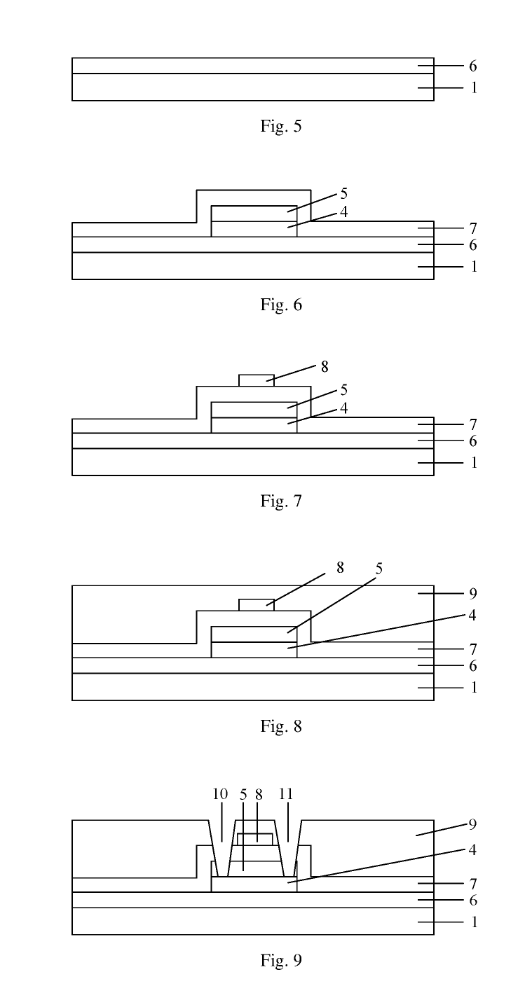

FIG. 6 is a schematic structure diagram of forming a gate insulating layer on the protective layer in the second embodiment of the present invention, and as shown in FIG. 6, a layer of silicon oxide thin film and a layer of silicon nitride thin film may be successively deposited on the base substrate which is formed with the active layer and the protective layer and obtained in the step 204 through a PECVD method, so as to form a gate insulating layer 7 of a double-layer structure.

At step 206, a gate is formed on the gate insulating layer.

FIG. 7 is a schematic structure diagram of forming a gate on the gate insulating layer in the second embodiment of the present invention, as shown in FIG. 7, one or more layers of metal thin films may be formed on the gate insulating layer 7 through a sputter coating technique, and then the metal thin film is patterned into a gate 8 by using the patterning process.

At step 207: a passivation layer is formed on the gate.

FIG. 8 is a schematic structure diagram of forming a passivation layer on the gate in the second embodiment of the present invention, and as shown in FIG. 8, a layer of silicon oxide thin film and a layer of silicon nitride thin film may be successively deposited on the base substrate formed with the gate and obtained in the step 206 through a PECVD method, to form a passivation layer 9 of a double-layer structure.

At step 208, a first via hole and a second via hole are respectively formed in positions, corresponding to two ends of the active layer, on the passivation layer, the gate insulating layer and the protective layer.

FIG. 9 is a schematic structure diagram of forming a first via hole and a second via hole in the second embodiment of the present invention, and as shown in FIG. 9, a first via hole 10 and a second via hole 11 may be respectively formed in positions, corresponding to two ends of the active layer, on the passivation layer 9, the gate insulating layer 7 and the protective layer 5 through an etching process.

At step 209, a source and a drain are formed on the passivation layer, the source being connected to the active layer through the first via hole, and the drain being connected to the active layer through the second via hole.

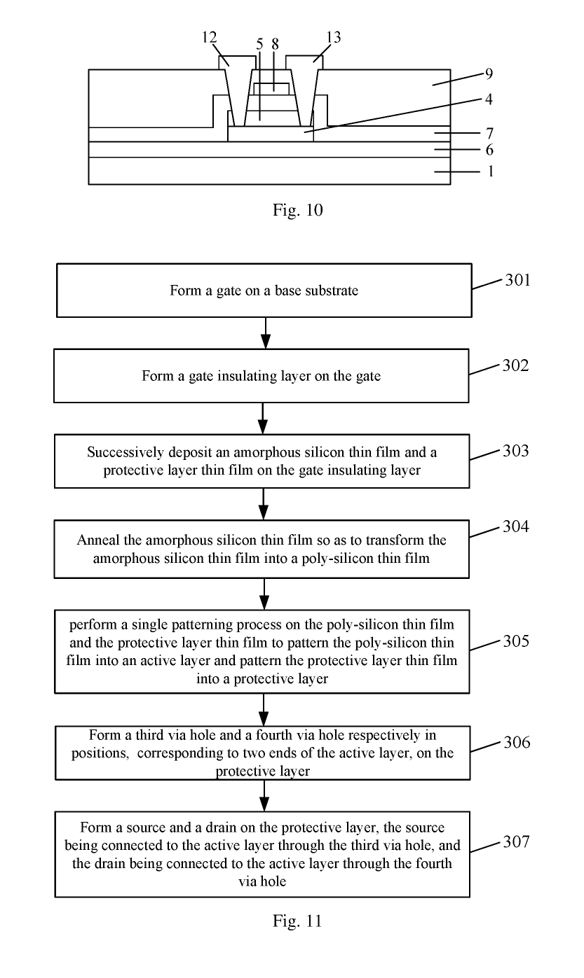

FIG. 10 is a schematic structure diagram of forming a source and a drain on the passivation layer in the second embodiment of the present invention, as shown in FIG. 10, firstly, one or more layers of metal thin films may be formed on the passivation layer through the sputter coating technique, and then the metal thin film is patterned into a source 12 and a drain 13 by using the patterning process, wherein the source 12 is connected to the active layer 4 through the first via hole 10, and the drain 13 is connected to the active layer 4 through the second via hole 11.

The second embodiment of the present invention further provides a thin-film transistor which may be prepared through the steps 201 to 209, and the structure of the thin-film transistor may be apparent with reference to FIG. 10. Specifically, the thin-film transistor includes an active layer 4 formed on a base substrate 1 and a protective layer 5 formed on the active layer 4, and the pattern of the protective layer 5 is the same as that of the active layer 4. A gate insulating layer 7 is formed on the protective layer 5; a gate 8 is formed on the gate insulating layer 7; a passivation layer 9 is formed on the gate 8; a first via hole 10 and a second via hole 11 are respectively formed in positions, corresponding to two ends of the active layer 4, on the passivation layer 9, the gate insulating layer 7 and the protective layer 5; and a source 12 and a drain 13 are formed on the passivation layer 9, the source 12 is connected to the active layer 4 through the first via hole 10, and the drain 13 is connected to the active layer 4 through the second via hole 11.

As another specific implementation of the present invention, FIG. 11 is a flow diagram of a preparation method of a thin-film transistor provided by a third embodiment of the present invention, as shown in FIG. 11, the thin-film transistor is a bottom gate type thin-film transistor, and the preparation method of the thin-film transistor includes steps 301 to 307.

At step 301, a gate is formed on a base substrate.

At step 302, a gate insulating layer is formed on the gate.

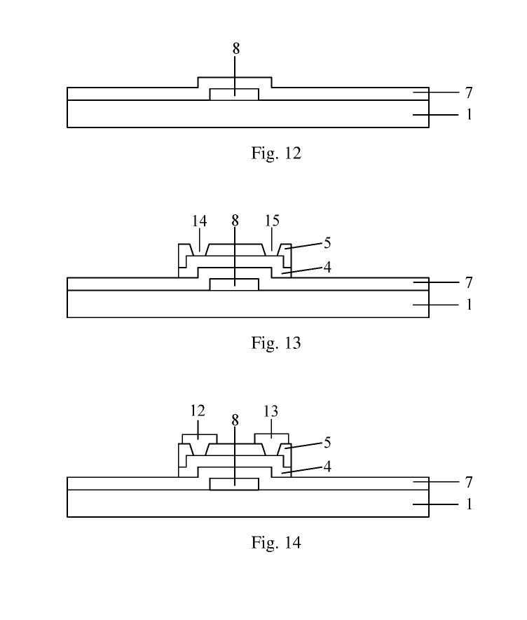

FIG. 12 is a schematic structure diagram of forming a gate and a gate insulating layer in the third embodiment of the present invention, as shown in FIG. 12, firstly, one or more layers of metal thin films may be formed on a base substrate 1 through a sputter coating technique, and then the metal thin film is patterned into a gate 8 by using the patterning process. Next, a layer of silicon oxide thin film and a layer of silicon nitride thin film may be successively deposited on the gate 8 and the base substrate 1 through a PECVD method, to form a gate insulating layer 7 of a double-layer structure.

At step 303, an amorphous silicon thin film and a protective layer thin film are successively deposited on the gate insulating layer.

At step 304, the amorphous silicon thin film is annealed so as to transform the amorphous silicon thin film into a poly-silicon thin film.

At step 305, a single patterning process is performed on the poly-silicon thin film and the protective layer thin film to pattern the poly-silicon thin film into an active layer and pattern the protective layer thin film into a protective layer.

The specific processes of the step 303 to step 305 may be apparent with reference to the specific description of the step 101 to step 103 in the first embodiment, and are not repeatedly described here.

At step 306, a third via hole and a fourth via hole are respectively formed in positions, corresponding to two ends of the active layer, on the protective layer.

FIG. 13 is a schematic structure diagram of forming a third via hole and a fourth via hole in the third embodiment of the present invention, and as shown in FIG. 13, a third via hole 14 and a fourth via hole 15 may be respectively formed in positions, corresponding to two ends of the active layer 4, on the protective layer 5 through an etching process.

At step 307, a source and a drain are formed on the protective layer, the source being connected to the active layer through the third via hole, and the drain being connected to the active layer through the fourth via hole.

FIG. 14 is a schematic structure diagram of forming a source and a drain on the protective layer in the third embodiment of the present invention, as shown in FIG. 14, firstly, one or more layers of metal thin films may be formed on the protective layer through the sputter coating technique, and then the metal thin film is patterned into a source and a drain by using the patterning process, wherein the source 12 is connected to the active layer 4 through the third via hole 14, and the drain 13 is connected to the active layer 4 through the fourth via hole 15.

The third embodiment of the present invention further provides a thin-film transistor which may be prepared through the steps 301 to 307, and the structure of the thin-film transistor may be apparent with reference to FIG. 14. Specifically, the thin-film transistor includes: a gate 8 formed on a base substrate 1, a gate insulating layer 7 formed on the gate 8, an active layer 4 formed on the gate insulating layer 7, a protective layer 5 which is formed on the active layer 4, and whose pattern is the same as that of the active layer 4, a third via hole 14 and a fourth via hole 15 respectively formed in positions, corresponding to two ends of the active layer 4, on the protective layer 5, and a source 12 and a drain 13 formed on the protective layer 5, the source 12 being connected to the active layer 4 through the third via hole 14, and the drain 13 being connected to the active layer 4 through the fourth via hole 15.

A fourth embodiment of the present invention provides an array substrate and a display panel, wherein the array substrate includes thin-film transistors, each of which may be the thin-film transistor in any one of the first to the third embodiments, and the preparation method of the thin-film transistor may be the preparation method in a corresponding embodiment among the first to the third embodiments.

The display panel provided by the embodiment includes an array substrate which is the above-described array substrate. The display panel specifically may be, for example, a liquid crystal display panel or an organic light emitting display (OLED) panel.

It may be understood that the above implementations are merely exemplary implementations adopted for describing the principle of the present invention, but the present invention is not limited thereto. For a person of ordinary skill in the art, various variations and improvements may be made without departing from the spirit and essence of the present invention, and those variations and improvements should also be regarded as falling into the protection scope of the present invention.

1. A preparation method of a thin-film transistor, comprising steps of:
successively depositing an amorphous silicon thin film and a protective layer thin film on a base substrate;
annealing the amorphous silicon thin film so as to transform the amorphous silicon thin film into a poly-silicon thin film; and
performing a single patterning process on the poly-silicon thin film and the protective layer thin film to pattern the poly-silicon thin film into an active layer and pattern the protective layer thin film into a protective layer.

2. The preparation method of a thin-film transistor according to claim 1, wherein the thin-film transistor is a top gate type thin-film transistor, and after the step of performing a single patterning process on the poly-silicon thin film and the protective layer thin film, the preparation method further comprises steps of:
forming a gate insulating layer on the protective layer;
forming a gate on the gate insulating layer;
forming a passivation layer on the gate;
forming a first via hole and a second via hole respectively in positions, corresponding to two ends of the active layer, on the passivation layer, the gate insulating layer and the protective layer; and
forming a source and a drain on the passivation layer, the source being connected to the active layer through the first via hole, and the drain being connected to the active layer through the second via hole.

3. The preparation method of a thin-film transistor according to claim 2, wherein before the step of successively depositing an amorphous silicon thin film and a protective layer thin film on a base substrate, the preparation method further comprises a step of:
forming a buffer layer on the base substrate.

4. The preparation method of a thin-film transistor according to claim 1, wherein the thin-film transistor is a bottom gate type thin-film transistor, and before the step of successively depositing an amorphous silicon thin film and a protective layer thin film on a base substrate, the preparation method further comprises steps of:
forming a gate on the base substrate; and
forming a gate insulating layer on the gate;
after the step of performing a single patterning process on the poly-silicon thin film and the protective layer thin film, the preparation method further comprises steps of:
forming a third via hole and a fourth via hole respectively in positions, corresponding to two ends of the active layer, on the protective layer; and
forming a source and a drain on the protective layer, the source being connected to the active layer through the third via hole, and the drain being connected to the active layer through the fourth via hole.

5. The preparation method of a thin-film transistor according to claim 1, wherein before the step of annealing the amorphous silicon thin film, the preparation method further comprises a step of:
dehydrogenizing the amorphous silicon thin film at a high temperature.

6. The preparation method of a thin-film transistor according to claim 1, wherein the protective layer is made of silicon oxide.

7. The preparation method of a thin-film transistor according to claim 2, wherein the protective layer is made of silicon oxide.

8. The preparation method of a thin-film transistor according to claim 3, wherein the protective layer is made of silicon oxide.

9. The preparation method of a thin-film transistor according to claim 4, wherein the protective layer is made of silicon oxide.

10. The preparation method of a thin-film transistor according to claim 5, wherein the protective layer is made of silicon oxide.

11. The preparation method of a thin-film transistor according to claim 1, wherein the thickness of the protective layer ranges from 30 nm to 40 nm.

12. The preparation method of a thin-film transistor according to claim 2, wherein the thickness of the protective layer ranges from 30 nm to 40 nm.

13. The preparation method of a thin-film transistor according to claim 3, wherein the thickness of the protective layer ranges from 30 nm to 40 nm.

14. A thin-film transistor, comprising: an active layer formed on a base substrate and a protective layer formed on the active layer, the pattern of the protective layer being the same as that of the active layer.

15. The thin-film transistor according to claim 14, wherein the thin-film transistor is a top gate type thin-film transistor, and the thin-film transistor further comprises:
a gate insulating layer formed on the protective layer;
a gate formed on the gate insulating layer;
a passivation layer formed on the gate;
a first via hole and a second via hole respectively formed in positions, corresponding to two ends of the active layer, on the passivation layer, the gate insulating layer and the protective layer, and
a source and a drain formed on the passivation layer, the source being connected to the active layer through the first via hole, and the drain being connected to the active layer through the second via hole.

16. The thin-film transistor according to claim 14, wherein the thin-film transistor is a bottom gate type thin-film transistor, and the thin-film transistor further comprises:
a gate formed on the base substrate;
a gate insulating layer formed on the gate;
a third via hole and a fourth via hole respectively formed in positions, corresponding to two ends of the active layer, on the protective layer, and
a source and a drain formed on the protective layer, the source being connected to the active layer through the third via hole, and the drain being connected to the active layer through the fourth via hole.

17. The thin-film transistor according to claim 14, wherein the protective layer is made of silicon oxide.

18. The thin-film transistor according to claim 14, wherein the thickness of the protective layer ranges from 30 nm to 40 nm.

19. An array substrate, comprising the thin-film transistor according to claim 14.

20. A display device, comprising the array substrate according to claim 19.
